(19) United States
(12) Patent Application Publication
(10) Pub. No.: US 2025/0279342 A1
(43) Pub. Date: Sep. 4, 2025

(54) METAL SEED LAYERS WITH DIFFERENT SHEET RESISTANCES IN INTEGRATED CIRCUIT PACKAGES

(71) Applicant: Intel Corporation, Santa Clara, CA (US)

(72) Inventors: Aleksandar Aleksov, Chandler, AZ (US); Henning Braunisch, Phoenix, AZ (US); Jeremy Ecton, Gilbert, AZ (US); Sashi Shekhar Kandanur, Chandler, AZ (US); Srinivas Venkata Ramanuja Pietambaram, Chandler, AZ (US); Neelam Prabhu Gaunkar, Chandler, AZ (US); Michael Ziad Serhan, Tempe, AZ (US)

(21) Appl. No.: 18/592,931

(22) Filed: Mar. 1, 2024

(51) Int. Cl. H01L 23/498; H01L 21/48; H01L 23/00; H01L 23/538

(52) U.S. Cl. CPC H01L 23/49827; H01L 21/486; H01L 23/49866; H01L 23/5383; H01L 24/16; H01L 24/17; H01L 24/32; H01L 24/73; H01L 2224/16227; H01L 2224/1703; H01L 2224/32225; H01L 2224/73204

(57) ABSTRACT

Metal seed layers with different sheet resistances in integrated circuit packages are disclosed. An integrated circuit package includes: a substrate having a first surface and a second surface opposite the first surface, and a first seed layer on a sidewall of an opening in the substrate. The opening is to extend from the first surface toward the second surface. The integrated circuit package also includes a second seed layer on the first surface of the substrate. The second seed layer is spaced apart from the opening.

### FIELD OF THE DISCLOSURE

This disclosure relates generally to integrated circuit packages and, more particularly, to metal seed layers with different sheet resistances in integrated circuit packages.

### BACKGROUND

In semiconductor device fabrication, layers of metal are often deposited on an underlying substrate using electroplating (also known as electrolytic plating or e-lytic plating). However, for electroplating to work, the underlying substrate needs to be electrically conductive. Accordingly, in instances where the underlying substrate is non-conductive, a thin metal seed layer is first deposited on the substrate to provide a conductive surface onto which a larger amount of metal can be added though electroplating. Inasmuch as the underlying substrate is non-conductive, the thin metal seed layer is deposited using processes other than electroplating. Processes other than electroplating that can be used to deposit a metal seed layer include chemodeposition processes (e.g., electroless or e-less plating), physical vapor deposition (PVD), sputtering, and chemical vapor deposition.

### BRIEF DESCRIPTION OF THE DRAWINGS

FIG. 1 illustrates an example integrated circuit (IC) package constructed in accordance with teachings disclosed herein.

FIG. 2 is a cross-sectional view of an example implementation of the package substrate of FIG. 1 after the deposition of two different metal seed layers on the substrate core and before other subsequent processing.

FIG. 3 is a top view of the example implementation of the package substrate shown in FIG. 2.

FIG. 4 is a cross-sectional view of another example implementation of the package substrate of FIG. 1.

FIG. 5 is a cross-sectional view of another example implementation of the package substrate of FIG. 1.

FIGS. 6-17 illustrate different stages during an example fabrication process to manufacture an example inductor within a package substrate based on any one of the example implementations shown in FIGS. 2-5 of the package substrate of FIG. 1.

FIG. 18 illustrates another example substrate that includes an example inductor similar to what is shown in FIG. 17.

FIG. 19 illustrates another example substrate that includes an example inductor similar to what is shown in FIGS. 17 and/or 18.

FIGS. 20-25 illustrate stages in an example fabrication process to manufacture high aspect ratio vias within a semiconductor (e.g., silicon) substrate.

FIG. 26 is a flowchart representative of an example method to manufacture a substrate (e.g., a package substrate core, a semiconductor substrate, etc.) with different metal seed layers having different sheet resistances as disclosed herein.

FIG. 27 is a top view of a wafer including dies that may be included in an IC package constructed in accordance with teachings disclosed herein.

FIG. 28 is a cross-sectional side view of an IC device that may be included in an IC package constructed in accordance with teachings disclosed herein.

FIG. 29 is a cross-sectional side view of an IC device assembly that may include an IC package constructed in accordance with teachings disclosed herein.

FIG. 30 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Metal seed layers are employed for electroplating (e.g., electrolytic plating) a conductive material (e.g., metal) onto an underlying substrate that is not itself conductive. The metal seed layers provide conductive surfaces on underlying substrates that serve to complete a circuit between electrodes coupled to the substrates. In some instances, the metal used for the seed layer is the same as the metal subsequently deposited thereon through electroplating. However, in other instances, the seed layer and the electroplated metal are different.

In an ideal situation, a seed layer provides an equipotential plane when connected to electrodes during electroplating because an equipotential plane facilitates the uniform deposition of the electroplated metal across the surface of the seed layer. In practical reality, it may not be possible to achieve a truly equipotential plane. However, this ideal can be approached by using a seed layer with a relatively low sheet resistance. Sheet resistance is a measure of the resistivity of a thin sheet of material divided by the thickness of the material. Thus, a seed layer with a lower sheet resistance can be achieved by using a material that has a lower resistivity (e.g., is highly conductive) and/or by increasing the thickness of the seed layer.

Resistivity has the units of ohms-meters (Ωm). As such, dividing the resistivity by a thickness (with units of meters), results in the units of ohms (Ω) for sheet resistance. However, to distinguish sheet resistance from bulk or volume resistance (also having the units of ohms), the units of sheet resistance are commonly denoted as ohms per square (Ω/sq). Thus, as used herein, the units of sheet resistance will be referred to as ohms per square, which is dimensionally equivalent to ohms.

As noted above, a seed layer most closely provides an equipotential plane when the seed layer has a relatively low sheet resistance. A low sheet resistance is particularly important for electroplating metal across large areas. That is, if the underlying substrate is large, the sheet resistance of the seed layer needs to be relatively low to adequately carry current across the surface of the substrate without a significant voltage drop (e.g., to achieve a substantially equipotential plane). Examples of relatively large substrates include semiconductor (e.g., silicon) wafer and panels, which can be as much as 500 mm across or more. A common seed layer used in semiconductor fabrication process is copper with a thickness of at least 50 nanometers (nm) resulting in a sheet resistance of less than 0.5 ohm per square. Frequently, a copper seed layer is thicker (e.g., as much as 400 nm) to achieve an even lower sheet resistance of less than 0.1 ohms per square.

While a low sheet resistance seed layer facilitates the formation of an equipotential plane across the seed layer for improved electroplating, such low sheet resistances can have detrimental effects on the operation of inductors fabricated using magnetic materials electroplated onto such seed layers. Specifically, a material with a low resistivity (and, thus, a low sheet resistance) next to the magnetic material in an inductor will lower the impedance of the eddy current loop in the magnetic material, thereby significantly reducing the efficiency of the inductor. Accordingly, while a low sheet resistance material is useful as a seed layer when trying to uniformly deposit conductive material via electroplating across large areas, the low sheet resistance material can be problematic in specific areas where magnetic material is to be deposited by electroplating to fabricate an inductor. Rather, in these specific areas where an inductor is to be implemented, it is beneficial to plate the magnetic material onto a seed layer that has a relatively high resistivity and, thus, a relatively high sheet resistance (e.g., a sheet resistance greater than 1 ohms per square, greater than 2 ohms per square, greater than 3 ohms per square, greater than 5 ohms per square, greater than 10 ohms per square, greater than 25 ohms per square, greater than 50 ohms per square, greater than 100 ohms per square, etc.). However, as noted above, a challenge with using highly resistive materials for a seed layer is the difficulty in achieving an equipotential surface (especially across relatively wide areas) to facilitate the uniform deposition of conductive material onto the seed layer using electroplating processes. In short, there is a tradeoff between a low sheet resistance seed layer that facilitates uniform deposition of material across the surface to be plated (which is particularly important when plating relatively large areas) and a high sheet resistance seed layer that improves the operation of an inductor implemented using magnetic material electroplated onto the seed layer.

Examples disclosed herein overcome the above challenges by implementing a hybrid seed layer architecture in which a high resistivity material (e.g., a sheet resistance greater than 1 ohms per square) is used as the seed layer in regions where magnetic material is to be deposited for fabrication of an inductor, and a low resistivity material (e.g., a sheet resistance of less than 0.5 ohms per square) is used as the seed layer in other regions. That is, in some examples, first (high) sheet resistance is at least twice the second (low) sheet resistance and sometimes much higher than the second (low) sheet resistance (e.g., at least 3 times as high, at least 5 times as high, at least 10 times as high, at least 25 times as high, at least 50 times as high, etc.). Generally, inductors are implemented in plated through-holes (e.g., through glass vias (TGVs), through core vias (TCVs)) that are relatively small in size (e.g., through holes with lengths less than 20 mm and often significantly less (e.g., less than 10 mm, less than 5 mm, less than 3 mm, less than 2 mm, less than 1 mm, etc.)) relative to the overall size of a semiconductor panel or wafer being processed (e.g., as much as 500 mm across). The small size of the inductors means that there is less concern of there being significant variations in the current density across the seed layer in that region (e.g., a non-equipotential plane). As such, there is less concern for the non-uniform plating of magnetic material across the relatively small region. In fact, simulations of the profile of material electroplated onto a relatively high sheet resistance seed layer (of 10 ohms per square) within a TGV revealed almost no difference in the cross-sectional profile of the material being electroplated onto a standard copper seed layer with a relatively low sheet resistance (of less than 0.1 ohms per square). Further, by using a low resistivity material everywhere else across a semiconductor panel or wafer, a substantially equipotential surface can be achieved to facilitate the uniform plating of conductive material across relatively large areas (e.g., the entire panel or wafer).

While the hybrid seed layer architecture disclosed herein is useful for applications that involve the fabrication of inductors, examples disclosed herein are not limited thereto. Multiple different seed layers with different sheet resistances can be used in other scenarios and/or for different purposes. For instance, in some examples, electroplating may be desired in relatively narrow (e.g., high aspect ratio) vias within a substrate. The thickness of a standard (relatively low sheet resistance) metal seed layer may fill too much of such vias so that there is insufficient space to reliably fill the rest of the via with an electroplated metal. That is, in some such scenarios, a narrow/high aspect ratio plated via fabricated using known methods may have voids or defects because of the unreliable nature of the electroplating process due to the overly thick seed layer. Such concerns can be overcome by using a much thinner seed layer. However, as discussed above, the thinner the seed layer, the higher the sheet resistance of the seed layer. So long as a thicker (e.g., low sheet resistance) seed layer is on the outer surface of the substrate to carry current up to the via, the thin seed layer within the via can provide sufficient conductivity to enable electroplating without taking up space within the via so that the electroplating will result in the reliable deposition of metal to fill the via.

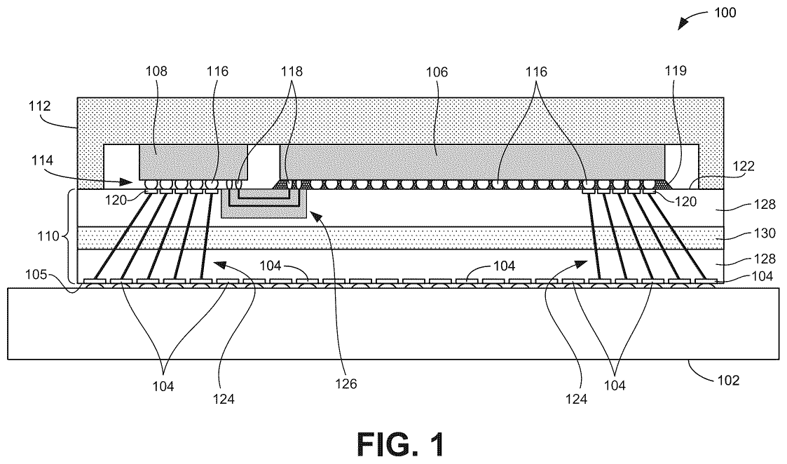

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package 100. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, the second level interconnects are used to electrically couple the IC package 100 to some component other than a circuit board (e.g., an interposer, another IC package, etc.). In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path (e.g., a continuous electrical signal path) between the interconnects 114 of the dies 106, 108 and the pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

In some examples, an underfill material 119 is disposed between the dies 106, 108 and the package substrate 110 around and/or between the first level interconnects 114 (e.g., around and/or between the core bumps 116 and/or the bridge bumps 118). In the illustrated example, only the first die 106 is associated with the underfill material 119. However, in other examples, both dies 106, 108 are associated with the underfill material 119. In other examples, the underfill material 119 is omitted. In some examples, the mold compound 112 is used as an underfill material that surrounds the first level interconnects 114.

In some examples, the IC package 100 includes additional passive components, such as surface-mount resistors, capacitors, and/or inductors disposed the bottom (external) surface 105 of the package substrate 110 and/or the top (inner) surface 122 of the package substrate 110.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within buildup regions 128 on one or both sides of a substrate core 130 (e.g., a base substrate) in the package substrate 110. In such examples, the buildup regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is an organic substrate or core (e.g., an epoxy-based prepreg layer). In other examples, the substrate core 130 is an inorganic dielectric. In some examples, the substrate core 130 is a glass substrate or core. In some such examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In some examples, glass substrates (e.g., the glass core 130) include at least one glass layer and do not include epoxy and do not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plan view, with the layers above and below the core (e.g., substantially coextensive with the buildup regions 128). The substrate core 130, whether an organic core or a glass core, provides stiffness and mechanical support or strength for the package substrate 110 and the rest of the package 100. Thus, the substrate core 130 is an example means for strengthening the package substrate 110. In some examples, the thickness of the core 130 is driven by the size (e.g., footprint) of the package 100. For example, in some instances, larger packages 100 include a substrate 110 with a larger (e.g., thicker) core 130 as compared with smaller packages 100 where the core does not need to be as thick.

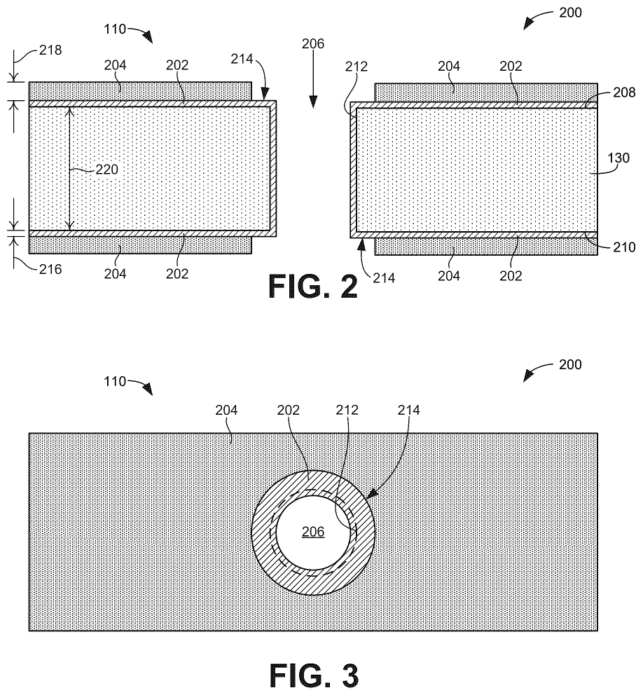

FIG. 2 is a cross-sectional view of an example implementation 200 of the package substrate 110 of FIG. 1 after the deposition of two different metal seed layers 202, 204 on the substrate core 130 and before other subsequent processing. FIG. 3 is a top view of the example implementation 200 of the package substrate 110 of FIG. 2. In this example, the core 130 includes an opening 206 (e.g., a through-hole, a via (e.g., a TCV, a TGV, etc.)) that extends all the way through the core 130 from a first (outer) surface 208 of the core 130 to a second (outer) surface 210 of the core. As shown in the illustrated example, the first seed layer 202 is deposited on both outer surfaces 208, 210 of the core 130 as well as along a sidewall 212 (e.g., wall, inner surface) of the opening 206. More particularly, in this example, the first seed layer 202 conformally coats the exposed (e.g., all exterior) surfaces of the core 130 such that the portion of the first seed layer on the outer surfaces 208, 210 is a continuous extension of the portion of the first seed layer 202 within the opening 206 on the sidewall 212.

In contrast with the first seed layer 202 (that extends into the opening 206), the second seed layer 204 is spaced apart from an interior of the opening 206. That is, as shown in FIG. 1, the second seed layer 204 is disposed on the outer surfaces 208, 210 of the core 130 but excluded from the sidewall 212 of the opening 206. In this example, the second seed layer 204 is not in direct contact with the core 130 because the first seed layer 202 is positioned between the core 130 and the second seed layer 204. As shown in the illustrated example, the second seed layer 204 extends along and covers a majority of the outer surfaces 208, 210 and, thus, covers a majority of the first seed layer 202 along the outer surfaces 208, 210. However, in some examples, portions 214 of the first seed layer 202 on the outer surfaces 208, 210 that surround the ends of the opening 206 are not covered by (e.g., are spaced apart from) the second seed layer 204.

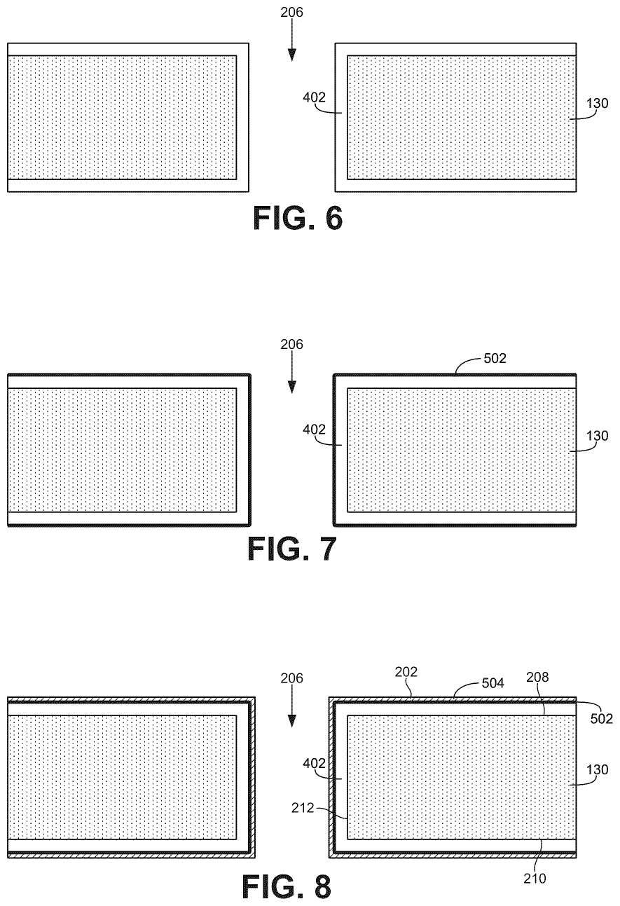

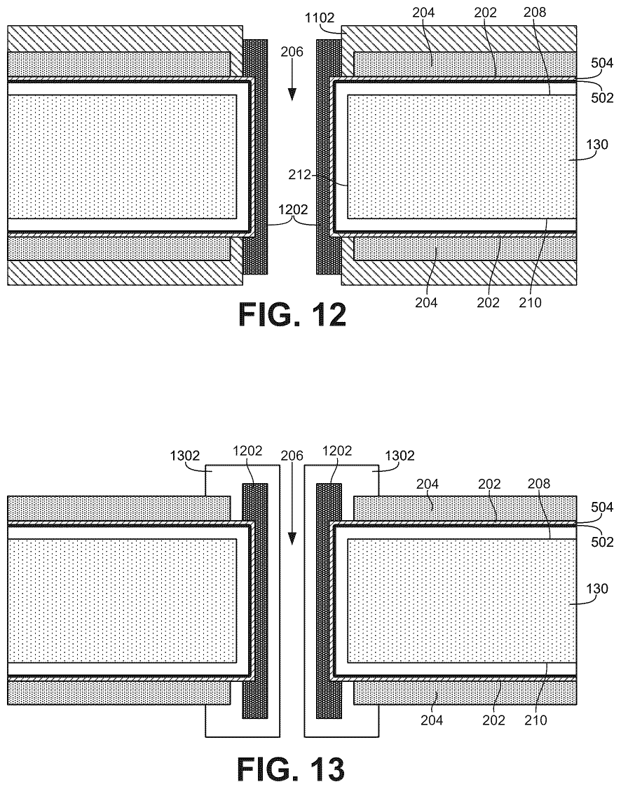

In some examples, the opening 206 corresponds to the location for an inductor in the package substrate 110. The fabrication of an example inductor is described further below in connection with FIGS. 6-17. On a general level, an inductor fabricated within the opening 206 includes a magnetic material (e.g., the magnetic material 1202 of FIGS. 12-17) disposed adjacent the sidewall 212 of the opening 206 so as to surround a conductive core extending through the opening 206. In some examples, the magnetic material 1202 is deposited along the sidewall 212 of the opening 206 using an electroplating process. To electroplate the sidewall 212 with the magnetic material 1202, the sidewall 212 needs to be conductive. It is for this reason that the sidewall 212 is lined with the first seed layer 202. That is, the magnetic material 1202 cannot be directly plated to the sidewall 212 of the opening 206 because the core 130 is not itself conductive. Instead, the first seed layer 202 is first deposited to provide conductivity along the sidewall to enable the subsequent electroplating process of the magnetic material 1202. In other words, as shown in FIG. 12 discussed in further detail below, although the magnetic material 1202 is to extend along and be adjacent to the sidewall 212, the first seed layer 202 is positioned between the magnetic material 1202 and the sidewall 212.

Using a relatively low sheet resistance material as the seed layer for the electroplating of the magnetic material 1202 can significantly undermine the efficiency of a resulting inductor by lowering the impedance of the eddy current loop in the magnetic material. Accordingly, in some examples, the first seed layer 202 has a relatively high sheet resistance. As used herein, a relatively high sheet resistance is a sheet resistance greater than 1 ohms per square. In some examples, the sheet resistance of the first seed layer 202 is much higher than 1 ohms per square (e.g., at least 2 ohms per square, at least 3 ohms per square, at least 5 ohms per square, at least 10 ohms per square, at least 25 ohms per square, at least 50 ohms per square, at least 100 ohms per square, etc.).

Inasmuch as the second seed layer 204 is spaced apart from the opening 206, the sheet resistance of the second seed layer 204 does not have a significant effect on the operation of the magnetic inductor within the opening 206. However, the sheet resistance of the second seed layer 204 will have a significant effect on how uniformly conductive material will be deposited at other locations across the core 130. Specifically, in this example, the second seed layer 204 serves as the basis for the deposition of conductive traces, via pads, and/or other conductive features that span the area of the core 130. That is, unlike the localized (relatively small) area of the opening 206 into which the magnetic material 1202 is plated, conductive material is to be plated across a wide area associated with the second seed layer 204. As such, uniformity in the deposition of such conductive material depends on the second seed layer 204 providing something approximating an equipotential plane. Accordingly, in some examples, the second seed layer 204 has a relatively low sheet resistance (e.g., lower than the sheet resistance of the first seed layer 202). As used herein, a low sheet resistance is a sheet resistance less than or equal to 0.5 ohms per square. In some examples, the sheet resistance of the second seed laver 204 is much lower than 0.5 ohms per square (e.g., less than or equal to 0.1 ohms per square or less).

The sheet resistance of a seed layer is directly proportional to the resistivity of the material used in the seed layer and inversely proportional to the thickness of the seed layer. Accordingly, in some examples, the differences in sheet resistance between the first and second seed layers 202, 204 is due to differences in at least one of the materials used in each seed layer 202, 204 or the thickness of each seed layer 202, 204. For instance, in some examples as shown in FIG. 2, a first thickness 216 of the first seed layer 202 is less than a second thickness 218 of the second seed layer 204. In some examples, the second thickness 218 is significantly larger than the first thickness (e.g., at least twice as thick, at least five times as thick, at least ten times as thick, etc.). More particularly, in some examples, the first thickness 216 is between approximately 4 nm and approximately 20 nm (e.g., less than 20 nm, less than 15 nm, less than 10 nm, less than 5 nm, etc.). In some examples, the first thickness 216 can be greater than 20 nm or less than 4 nm. In some examples, the second thickness 218 is between approximately 50 nm and approximately 400 nm. In some examples, the second thickness 218 can be less than 50 nm or greater than 400 nm.

As noted above, in addition to the different thicknesses 216, 218, in some examples, the different seed layers 202, 204 are composed of different materials having different resistivities. More particularly, in some examples, the second seed layer 204 includes copper because copper has low resistivity, whereas the first seed layer 202 includes a metal with a higher specific resistivity than copper. In some examples, the resistivity of the first seed layer 202 is significantly higher than copper (e.g., twice as high, three times as high, four times as high, ten times as high, twenty times as high, etc.). Although the first seed layer 202 includes materials that have higher resistivity (e.g., are less conductive) than copper, the materials used for the first seed layer 202 are selected to be at least sufficiently conductive to enable electroplating onto the first seed layer 202 within the opening 206. In some examples, the first seed layer 202 includes at least one of ruthenium, titanium, tantalum, manganese, or cobalt. In some examples, the same material (e.g., copper) may be used for both the first seed layer 202 and the second seed layer 204. In such examples, the difference in sheet resistance is achieved based on the differences in thickness of the two seed layers 202, 204.

Notably, the high resistivity of the first seed layer 202 within the opening 206 is not a large concern for the effectiveness of electroplating within the opening 206 because of the relatively short length of the first seed layer 204 over which a metal is to be plated. Specifically, the path length of the first seed layer 202 over which metal is to be plated is related to the length (or depth) of the opening 206, which corresponds to a third thickness 220 of the core 130. More particularly, the path length for which the first seed layer 202 is needed corresponds to approximately half the length of the opening 206 (e.g., half the third thickness 220) because the metal to be plated within the opening 206 can approach the first seed layer 202 from either end of the opening 206. Known cores 130 are less than 1.5 mm thick. Thus, using known cores, the maximum path length for the first seed layer 202 is less than approximately 750 micrometers (um). This is a much shorter distance than the entire span of the outer surfaces 208, 210 of the core 130 onto which material is to be plated using the second seed layer 204. Hence the reason for the lower resistivity of the second seed layer 204 relative to the first seed layer 202. Specifically, the lower resistivity of the second seed layer 204 enables electrical current to reach any location along the second seed layer 204 without a significant voltage drop (e.g., to provide an equipotential plane). This ensures that conductive material electroplated onto the second seed layer 204 is deposited substantially uniformly across the entire outer surfaces 208, 210 of the core 130. The low resistivity of the second seed layer 204 also ensures electrical current reaches the opening 206 (or at least the first seed layer 202 adjacent the opening 206) with relatively little (e.g., negligible) voltage drop, and then the first seed layer can carry the current the last (relatively small) distance into the opening 206 to enable electroplating of the inside of the opening 206.

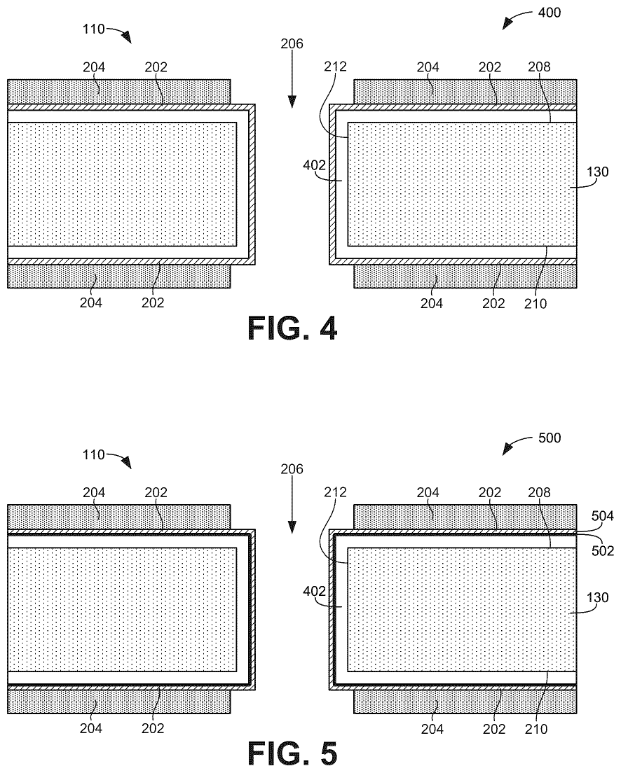

FIG. 4 is a cross-sectional view of another example implementation 400 of the package substrate 110 of FIG. 1. Many of the features shown in FIG. 4 are the same or similar to the features shown and described above in connection with FIGS. 2 and 3. Accordingly, the same reference numbers used in FIGS. 2 and 3 are used for the same features shown in FIG. 4 and the associated description of those features described above applies equally to the example of FIG. 4. The example implementation 400 of FIG. 4 differs from the example implementation 200 of FIGS. 2 and 3 in that a stress buffer layer 402 is deposited on the outer surfaces 208, 210 and the sidewall 212 of the opening 206 of the core 130 prior to the deposition of the first seed layer 202. That is, as shown in FIG. 4, the stress buffer layer 402 is positioned between the core 130 and the first seed layer 202. In some examples, the stress buffer layer 402 is a polymeric layer composed of a relatively low modulus material (e.g., a polymer such as parylene) that can absorb stress through deformation to protect the structural integrity of the core 130. The stress buffer layer 402 is particularly suitable in examples where the core 130 is a glass core. However, the stress buffer layer 402 may also be used in other examples that do not include a glass core.

FIG. 5 is a cross-sectional view of another example implementation 500 of the package substrate 110 of FIG. 1. Many of the features shown in FIG. 5 are the same or similar to the features shown and described above in connection with the example of FIGS. 2 and 3 and/or the example of FIG. 4. Accordingly, the same reference numbers used in FIGS. 2-4 are used for the same features shown in FIG. 5 and the associated description of those features described above applies equally to the example of FIG. 5. The example implementation 500 of FIG. 5 differs from the previous example implementations 200, 400 of FIGS. 2-4 in that the first seed layer 202 includes multiple different layers of material. Specifically, in this example, the first seed layer 202 includes an adhesion layer 502 and a protective cap layer 504. In some examples, the adhesion layer 502 is disposed directly on (e.g., is in contact with) the core 130 to facilitate adhesion of subsequently deposited layers onto the core 130 such as the protective cap layer 504 of the first seed layer 202 and/or the second seed layer 204. More particularly, in some examples, the adhesion layer 502 includes at least one of titanium or tantalum. In some examples, the protective cap layer 504 serves to protect the underlying adhesion layer 502 from contamination and/or oxidation. In some examples, the protective cap layer 504 includes ruthenium. In some examples, the protective cap layer 504 is thinner than the underlying adhesion layer. More particularly, in some examples, the adhesion layer 502 is between approximately 5 nm and approximately 15 nm and the protective cap layer is between approximately 2 nm (or less) and approximately 5 nm.

In the illustrated example of FIG. 5, the first seed layer 202 includes two separate layers of materials. In other examples, the first see layer 202 can include more than two layers of materials. In some examples, the second seed layer 204 may additionally or alternatively include multiple layers of materials. Further, multiple layers of materials in the first and/or second seed layers 202, 204 are not limited to the illustrated example of FIG. 5 but can also be implemented in other examples disclosed herein. That is, in some examples, one or both of the seed layers 202, 204 in FIGS. 2 and 3 and/or FIG. 4 may include multiple layers of material.

FIGS. 6-17 illustrate different stages during an example fabrication process to manufacture an example inductor within a package substrate based on any one of the example implementations 200, 400, 500 of FIGS. 2-5 of the package substrate 110 of FIG. 1. More particularly, FIG. 6 illustrates the stage of fabrication following the creation of the opening 206 within the core 130 and the deposition of the stress buffer layer 402. In some examples, the stress buffer layer 402 is deposited via sputtering, spin coating, physical vapor deposition (PVD), chemical vapor deposition (CVD), atomic layer deposition (ALD), and/or any other suitable deposition process. In some examples, as shown in FIG. 2, the stress buffer layer 402 can be omitted.

FIG. 7 illustrates a subsequent stage of fabrication after the deposition of the adhesion layer 502 onto the stress buffer layer 402 (or onto the core 130 if the stress buffer layer 402 is omitted). In some examples, the adhesion layer 502 is deposited via sputtering, spin coating, PVD, CVD, ALD, and/or any other suitable deposition process. FIG. 8 illustrates a subsequent stage of fabrication after the deposition of the protective cap layer 504 onto the adhesion layer 502. In some examples, the protective cap layer 504 is deposited via sputtering, spin coating, PVD, CVD, ALD, and/or any other suitable deposition process. In the illustrated example of FIG. 8, the adhesion layer 502 and the protective cap layer 504 collectively correspond to the first seed layer 202. As discussed above, in some examples, the first seed layer 202 includes a single layer of material. That is, in some examples, the adhesion layer 502 is omitted. Alternatively, in some examples, the protective cap layer 504 is omitted. Further, in some examples, the single layer of material in the first seed layer 202 is different than either of the layers 502, 504 in the first seed layer 202 shown in FIG. 8.

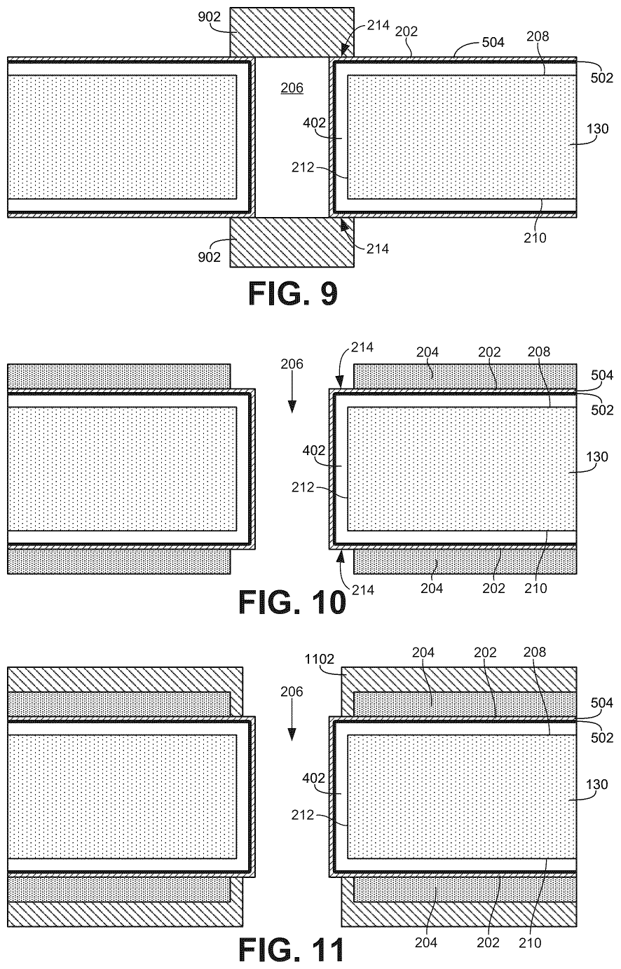

As shown in the illustrated example of FIG. 8, the first seed layer 202 extends along the outer surfaces 208, 210 of the core 130 as well as along the sidewall 212 of the opening 206 in the core 130. The first seed layer 202 along the sidewall 212 of the opening 206 is the only seed layer needed to enable electroplating within the opening 206. Accordingly, in some examples as represented in FIG. 9, the next stage in the manufacturing process involves the deposition and lithographic patterning of a resist layer 902 (e.g., a photoresist, a dry film resist, etc.) to cover the opening 206 while exposing portions of the first seed layer 202 along the outer surfaces 208, 210 of the core 130. In this manner, subsequent processing will not affect the interior of the opening 206. Specifically. FIG. 10 represents a subsequent stage of fabrication following the deposition of the second seed layer 204 onto the first seed layer 202 followed by the removal the resist layer 902. Inasmuch as the second seed layer 204 is deposited before the removal of the resist layer 902, the second seed layer 204 does not extend into the opening 206 or onto the portion 214 of the first seed layer 202 on the outer surfaces 208, 210 of the core 130 that is covered by the resist layer 902. That is, the resist layer 902 blocks or prevents the second seed layer 204 from being deposited within the opening 206. Although the first seed layer 202 is suitable to enable electroplating across the relatively short distance along the sidewall 212 of the opening 206, due to the relatively high sheet resistance of the first seed layer 202, electroplating across the much larger area associated with the outer surfaces 208, 210 of the core 130 is not a viable option. It is for this reason that the second seed layer 204 is added, which has a relatively low sheet resistance. In some examples, the second seed layer 204 is deposited via sputtering, spin coating, PVD, CVD, ALD, and/or any other suitable deposition process. FIG. 10 illustrates the completion of an example hybrid seed layer architecture with multiple different seed layers of different sheet resistances located at different locations on an underlying substrate (e.g., the core 130). The subsequent stages of fabrication details in connection with FIGS. 11-17 demonstrate how this hybrid seed layer architecture is used to fabricate an inductor.

FIG. 11 illustrates a subsequent stage of fabrication following the deposition and lithographic patterning of another resist layer 1102 (e.g., a photoresist, a dry film resist, etc.). As shown in FIG. 11, the second resist layer 1102 covers the second seed layer 204 while exposing the opening 206 and the first seed layer 202 on the sidewall 212 of the opening 206. FIG. 12 illustrates a subsequent stage of fabrication after the deposition of magnetic material 1202 along the sidewall 212 of the opening 206. In this example, the magnetic material 1202 is deposited through an electroplating process using the first seed layer 202 as the underlying conductive surface within the opening 206. More particularly, in some examples, the relatively low sheet resistance of the second seed layer 204 enables electrical current to reach the opening 206 (from a distant location on the core 130 (or associated panel and/or substrate) where electrodes are attached) and then the first seed layer 202 (with a much high sheet resistance) provides a path for the current to reach into the opening 206.

FIG. 13 illustrates a subsequent stage of fabrication following the removal of the second resist layer 1102 and subsequent deposition of a dielectric material 1302 over the magnetic material 1202. In some examples, the dielectric material 1302 is limited to the region surrounding the magnetic material 1202 based on one or more lithographic processes.

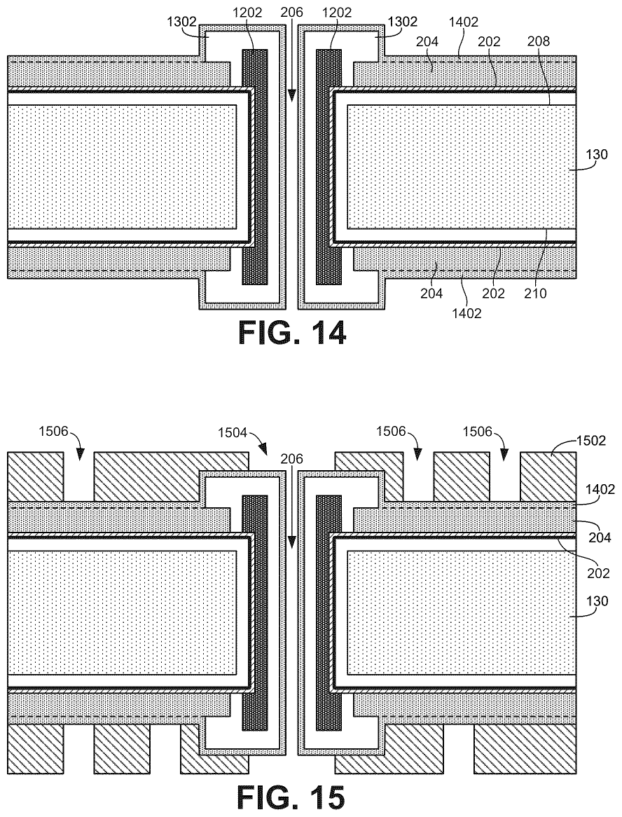

FIG. 14 illustrates a subsequent stage of fabrication following the deposition of a third metal seed layer 1402 over exposed surfaces including the second seed layer 204 and the dielectric material 1302. In this example, the second and third seed layers 204, 1402 are shown with the same shading and demarcated by a dashed line at the interface therebetween to indicate the third seed layer 1402 is implemented with the same material (e.g., copper) as the second seed layer 202. However, in other examples, the second and third see layers 204, 1402 can be implemented with different materials. The third seed layer 1402 provides a conductive surface overtop of the dielectric material 1302 within the opening 206 so that additional metal can be electroplated thereon during a subsequent fabrication process discussed below.

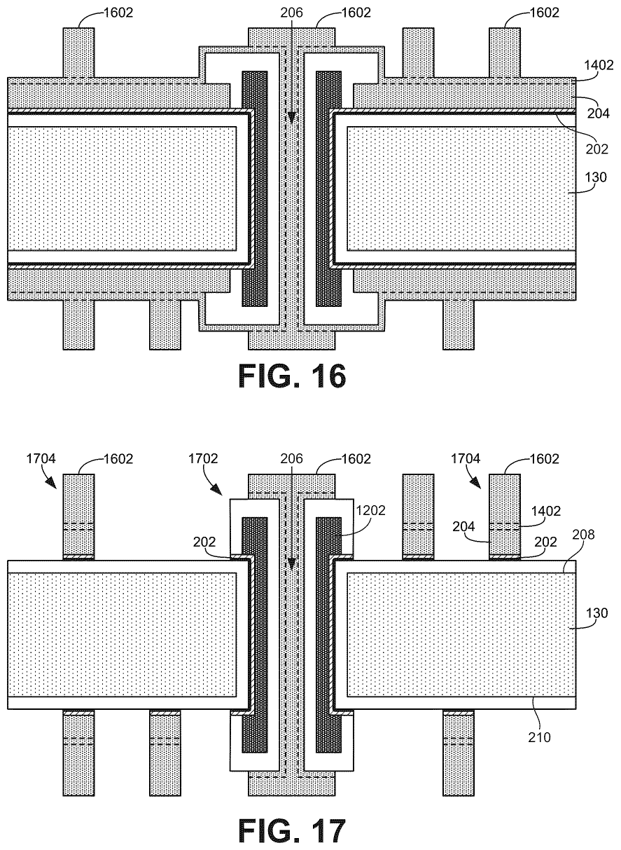

FIG. 15 illustrates a subsequent stage of fabrication following the deposition and lithographic patterning of another resist layer 1502 (e.g., a photoresist, a dry film resist, etc.). As shown in the illustrated example, the resist layer 1502 is patterned to include a first opening 1504 that exposes the opening 206 of the core 130 (lined with the third seed layer 1402) and other openings 1506 that expose other portions of the underlying third seed layer 1402. FIG. 16 illustrates a subsequent stage of fabrication following the deposition of a metal plating layer 1602 (via electroplating) onto the third seed layer 202 followed by the removal of the resist layer 1502. More particularly, in this example, the metal plating layer 1602 fills the central region of the opening 206 in the core 130 and also fills the other openings 1506 in the resist layer 1502. In this example, the metal plating layer 1602 and the underlying third seed layer 1402 are shown with the same shading and demarcated by a dashed line at the interface therebetween to indicate the metal plating layer 1602 is implemented with the same material (e.g., copper) as the third seed layer 1402. However, in other examples, the third seed layer 1402 and the metal plating layer 1602 can be implemented with different materials.

FIG. 17 illustrates a subsequent stage of fabrication following the removal of excess material including excess portions of the metal plating layer 1602 and excess portions of the first, second, and third seed layers 202, 204, 1402. In some examples, the excess portions are removed via an etching process (e.g., a wet etch, a dry etch, etc.). As shown in the illustrated example of FIG. 17, the remaining portion of the metal plating layer 1602 that filled the central region of the opening 206 (along with the third seed layer 1402) defines a core and contacts of an example plated magnetic inductor 1702 (e.g., a plated magnetic via (PMV)). Further, the portions of the metal plating layer 1602 deposited within the openings 1506 in the third resist layer 1502 (along with the first, second, and third seed layers 202, 204, 1402) define metal traces and/or routing 1704 (or other metal features) along the outer surfaces 208, 210 of the core 130. In this example, aside from the surfaces (e.g., ends) of the traces and/or routing 1704 closest to the core 130, the only other location of the first seed layer 202 is adjacent to the magnetic material 1202 within the opening 206 of the core 130. Having the first seed layer 202 (with a relatively high sheet resistance) adjacent to (e.g., in contact with) the magnetic material 1202 serves to improve the efficiency of the inductor 1702 relative to similar inductors that rely on known seed layers (with much lower sheet resistance) to plate the magnetic material.

After reaching the stage of fabrication represented by FIG. 17, the resulting package substrate may undergo subsequent processing such as laminating a layer of dielectric material followed by another metal layer to create the buildup regions 128 on either side of the core 130.

The different stages of the example fabrication process represented in FIGS. 6-17 are just one example process flow. Other process flows and/or additional processes not discussed above may be implemented during the manufacturing process. For instance, in some examples, an activator metal may be applied to the first seed layer 202 prior to the deposition of the second seed layer 204 (e.g., between the stages represented in FIGS. 9 and 10). Thereafter, the resist layer 902 may be removed and then the second seed layer 202 is selectively deposited on the areas with the activator.

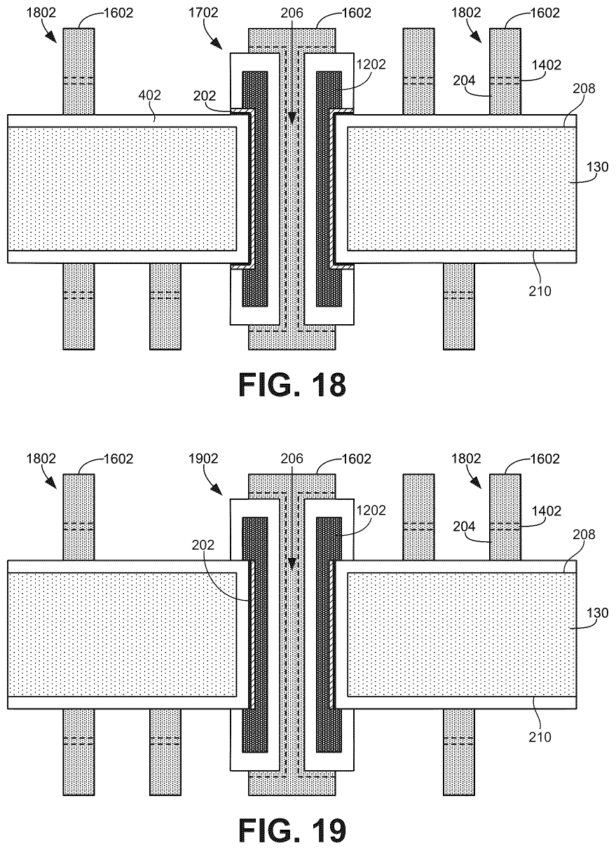

Further, in some examples, changes to the process flow described above can result in slightly modified final structures. For instance. FIG. 18 illustrates another example substrate that includes a similar inductor 1702 as shown and described in FIG. 17. However, unlike the example shown in FIG. 17, FIG. 18 includes different traces and/or routing 1802 that do not include the first seed layer 202. Instead, as shown in FIG. 18, the second seed layer 204 is in direct contact with the stress buffer layer 402 (or the core 130 if the stress buffer layer 402 is omitted). In some examples, the structure shown in FIG. 18 is achieved by changing the order of operations involved in the fabrication process outlined above. More particularly, in some such examples, the first resist layer 902 (shown in FIG. 9) can be added before the first seed layer 202 is added. The second seed layer may then be deposited directly onto the stress buffer layer 402 but blocked from entering the opening 206 because of the first resist layer 902. Thereafter, the first resist layer 902 is removed and the first seed layer 202 is deposited into the opening 206 and over the previously deposited second seed layer 204. In some such examples, the portion of the first seed layer 202 deposited over top of the second seed layer 204 is removed during a subsequent process (e.g., etching, grinding, etc.) before proceeding with the process as described above.

FIG. 19 illustrates another example substrate that is similar to FIG. 18 except that FIG. 19 includes a slightly different inductor 1902 in which the first seed layer 202 does not extend along any of the outer surfaces 208, 210 of the core 130. Instead, as shown in the illustrated example of FIG. 19, the first seed layer 202 is limited to within the interior of the opening 206. In some examples, the structure shown in FIG. 19 can be achieved by following the process flow substantially as outlined above in connection with FIGS. 6-17 above. However, after the stage represented in FIG. 8 (after the first seed layer 202 is deposited) and before the stage represented in FIG. 9 (before the first resist layer 902 is deposited) the portions of the first seed layer 202 on the outer surfaces 208, 210 are removed (via etching, grinding, etc.). The process can then proceed as outlined above.

As described above, using metal seed layers with relatively high sheet resistance within openings or vias in which magnetic material is to be electroplated to implement an inductor provide significant improvements over standard low sheet resistance seed layers. However, this is not the only advantage or useful application of a high sheet resistance seed layer in combination with a low resistance seed layer. Another useful application for high sheet resistance seed layers is to facilitate the electroplating of metal within relatively narrow and/or high aspect ratio openings and/or vias in a substrate. In such situations, a standard seed layer, which is relatively thick (e.g., between approximately 50 nm and approximately 400 nm) may not provide enough space leftover within an opening to enable proper plating of a metal within the opening. That is, the relatively thick seed layer in a narrow (e.g., high aspect ratio) via may impede the ability to fill the via with metal without creating void defects. By using a much thinner seed layer (e.g., less than 20 nm, less than 10 nm, less than 5 nm, etc.) there is more space for the plated metal to attach to the seed layer within a narrow via to properly fill the via with few, if any, void defects.

Notably, as discussed above, the sheet resistance of a seed layer is inversely proportional to the thickness of the seed layer. Thus, by reducing the thickness of the seed layer within a via, the corresponding sheet resistance for the seed layer within the via will increase. While a high sheet resistance is problematic to achieve an equipotential plane across a large area that extends over relatively large distances, for relatively small areas that extend over relatively short distances (e.g., the distance of a through-hole or through core via) this is less of a concern. Thus, a thin seed layer within a via is acceptable for reliable electroplating so long as there is a thicker seed layer (e.g., a seed layer with a lower sheet resistance) on the outer surface(s) of the substrate through which the via extends. This thicker seed layer serves the purpose of carrying current from electroplating electrodes up to the via with little to no voltage drop and then the thin seed layer within the via can carry the current the rest of the way into the via for effective plating.

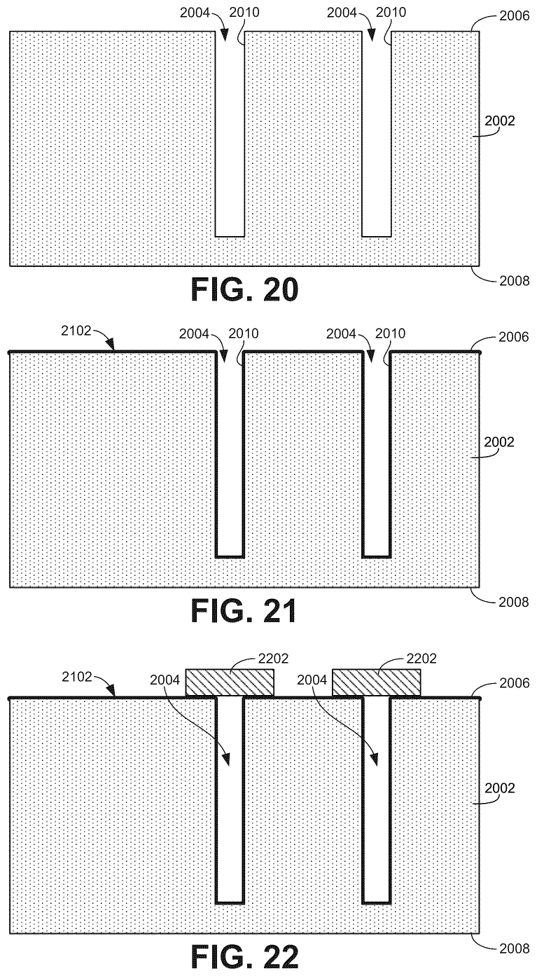

FIGS. 20-25 illustrate stages in an example fabrication process to manufacture high aspect ratio through core vias (e.g., openings, holes, through-silicon vias (TSVs)) within a semiconductor (e.g., silicon) substrate. Specifically, FIG. 20 shows a semiconductor (e.g., silicon) substrate 2002 that includes vias 2004 extending from a first surface 2006 of the substrate 2002 toward a second surface 2008 of the substrate 2002. In this example, the vias 2004 are blind vias or blind holes because they do not extend all the way from the first surface 2006 to the second surface 2008. However, in other examples, the vias 2004 may extend all the way through the substrate 2002. That is, in some examples, the vias 2004 are through-holes. In some examples, the vias 2004 are nano TSVs with a relatively high aspect ratio. That is, the vias 2004 have a relatively small width or diameter which is much less than the depth (e.g., height or length) of the vias 2004. In some examples, the vias 2004 include a liner and/or insulator along an inner sidewall 2010 of the vias 2004. In some examples, the liner and/or insulator may be omitted.

FIG. 21 illustrates the stage in the fabrication process following the deposition of a first metal seed layer 2102 onto exposed surfaces of the semiconductor substrate 2002. That is, as shown in FIG. 21, the first seed layer 2102 covers the first surface 2006 of the substrate and covers the sidewall 2010 (as well as the bottom end) of the vias 2004. In some examples, the first seed layer 2102 of FIG. 21 is the same or similar to the first seed layer 202 discussed above in connection with FIGS. 2-19. Accordingly, in some examples, the same or similar materials, the same or similar thicknesses, and/or the same or similar layers of multiple layers of materials described above apply equally with respect to this example. In some examples, the materials, thickness, and/or layers of different materials in the first seed layer 2102 of FIG. 21 may be different than what is described above in connection with FIGS. 2-19. Specifically, the example materials described above in connection with FIGS. 2-19 are employed to achieve as high of a sheet resistance as possible (while still being sufficiently conductive to enable electroplating) to reduce the impedance of the eddy current loop in the magnetic material of the associated inductor. In the example of FIG. 21, the via is not intended to implement an inductor and so having a high sheet resistance is less important. Thus, materials with a lower resistivity may be implemented for the first seed layer 2102 of FIG. 21 than would be used for the first seed layer 202 of FIGS. 2-19. While the resistivity of the material used for the first seed layer 2102 may be relatively low, the sheet resistance of the seed layer 2102 may still be relatively high because of the thinness of the first seed layer 2102. As noted above, in some examples, the thickness of the first seed layer 2102 is less than 20 nm (e.g., 15 nm or less, 10 nm or less, 5 nm or less, etc.). In some examples, the first seed layer 2102 is deposited via sputtering, spin coating, PVD, CVD, ALD, and/or any other suitable deposition process.

FIG. 22 represents a subsequent stage of fabrication following the deposition and lithographic patterning of a resist layer 2202 (e.g., a photoresist, a dry film resist, etc.) to cover the vias 2004 while exposing portions of the first seed layer 2102 along the first surface 2006 of the substrate 2002. This stage in the fabrication process is comparable to that represented above in connection with FIG. 9.

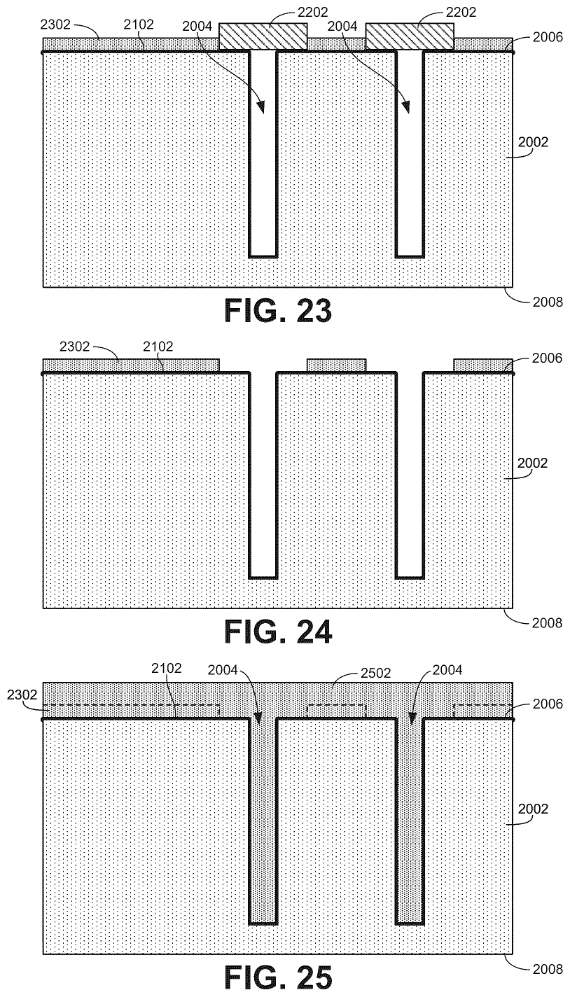

FIG. 23 represents a subsequent stage of fabrication following the deposition of a second seed layer 2302 onto the first seed layer 2102. Although the first seed layer 2102 is suitable to enable electroplating across the relatively short distance along the length of the vias 2004, due to the relatively high sheet resistance of the first seed layer 2102, electroplating across the much larger area associated with the first surface 2006 of the substrate 2002 is not a viable option. It is for this reason that the second seed layer 2302 is added, which has a relatively low sheet resistance (based on its much greater thickness). In some such examples, where electroplating along the first surface 2006 using the first seed layer 2102 is not possible, the second seed layer 204 is deposited via sputtering, spin coating, PVD, CVD, ALD, and/or any other suitable deposition process.

FIG. 24 represents a subsequent stage of fabrication following the removal of the resist layer 2202. This stage in the fabrication process is comparable to that represented above in connection with FIG. 10.

FIG. 25 represents a subsequent stage of fabrication following the deposition of a metal plating layer 2502 (via electroplating) onto the first and second seed layers 2102, 2302. More particularly, as shown in the illustrated example, the metal plating layer 2502 fills the vias 2004 in the substrate 2002 and also extends across the first surface 2006 of the substrate 2002 over the second seed layer 2302. In some examples, a subsequent etching process can remove excess portions of the metal plating layer 2502 (along with associated portions of the seed layers 2102, 2302) to define discrete regions of metal associated with tracing, routing, and/or other metal features. In other examples, another resist layer can be deposited and patterned over top of the first and second seed layers 2102, 2303 before the metal plating layer 2502 is added so that the material is only plated onto exposed portions of the first and second seed layers 2102, 2302. Further, other process flows are possible to achieve different structures. For instance, the process flow detailed in FIGS. 20-25 can be modified in a similar manner to what was described above in connection with FIGS. 18 and/or 19 to limit the first seed layer 2102 to regions within and/or adjacent to the vias 2004.

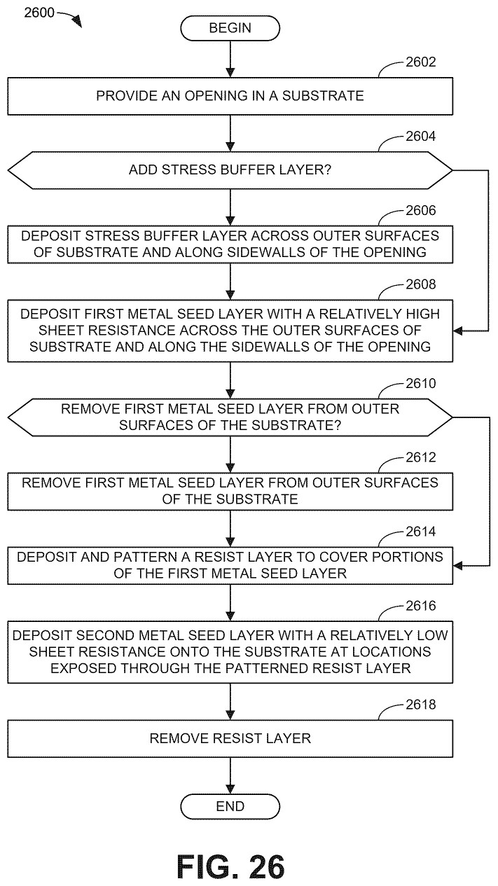

FIG. 26 is a flowchart representative of an example method 2600 to manufacture a substrate (e.g., a package core, a semiconductor substrate, etc.) with different metal seed layers having different sheet resistances as disclosed herein. More particularly, the example method of FIG. 26 can be followed to manufacture any of the example implementations 200, 300, 400 of the package substrate 110 shown in FIGS. 2-5 and/or the example semiconductor substrate assembly of FIG. 24 with an example hybrid seed layer architecture disclosed herein. In some examples, some or all of the operations outlined in the example method of FIG. 26 are performed automatically by fabrication equipment that is programmed to perform such operations. Although the example method of manufacture is described with reference to the flowchart illustrated in FIG. 26, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

Turning to FIG. 26 in detail, the example process begins at block 2602 by providing an opening that extends through a substrate. In some examples, the opening is a through-hole that extends all the way through the substrate. For instance, in some examples, the substrate of block 2602 corresponds to the substrate core 130 of FIGS. 2-19 and the opening of block 2602 corresponds to the opening 206 extending through the core 130. In other examples, the opening is a blind-hole that does not extend all the way through the substrate. For instance, in some examples, the substrate of block 2602 corresponds to the semiconductor substrate 2002 of FIGS. 20-25 and the opening of block 2602 corresponds to the vias 2004 in the semiconductor substrate 2002.

At block 2604, the example process involves determining whether to add a stress buffer layer. If so, the example process advances to block 2606 where a stress buffer layer (e.g., the stress buffer layer 402 of FIGS. 4 and/or 5) is deposited across outer surfaces (e.g., the outer surfaces 208, 210 of FIGS. 2-5, the outer surface 2006 of FIGS. 20-25) of the substrate and along sidewalls (e.g., the sidewalls 212, 2010) of the opening. The operation(s) associated with block 2606 are represented by FIG. 6 as described above. Thereafter, the example process advances to block 2608. If no stress buffer layer is to be added, the example process advances directly from block 2604 to block 2608.

At block 2608, the example process involves depositing a first metal seed layer (e.g., the first metal seed layer 202 of FIGS. 2-5, the first metal seed layer 2102 of FIGS. 20-25) with a relatively high sheet resistance across outer surfaces of the substrate and along the sidewalls of the opening. In some examples, the sheet resistance is relatively high based on using a material with a relatively high resistivity. In some examples, the sheet resistance is high based on the seed layer having a relatively small thickness. In some examples, both the material used for the first metal seed layer as well as the thickness of the layer contribute to the relatively high sheet resistance. In some examples, the first metal seed layer is deposited directly onto the substrate (e.g., when no stress buffer layer was added). In other examples, the first metal seed layer is deposited onto the stress buffer layer that is to be positioned between the first metal seed layer and the underlying substrate. The operation(s) associated with block 2608 are represented by FIGS. 6, 7, and/or 21 as described above.

At block 2610, the example process involves determining whether to remove the first metal seed layer from the outer surfaces of the substrate. In some examples, the first metal seed layer may be removed if the first metal seed layer is only needed along the sidewalls of the opening. If the first metal seed layer is to be removed, the example process advances to block 2612 where the first metal seed layer is removed from the outer surfaces of the substrate. Thereafter, the example process advances to block 2614. If none of the first metal seed layer is to be removed, the example process advances directly from block 2610 to block 2614.

At block 2614, the example process involves depositing and patterning a resist layer (e.g., the resist layer 902 of FIG. 9, the resist layer 2202 of FIG. 22) to cover portions of the first metal seed layer. In some examples, the portions covered by the resist layer correspond to areas w % here the second metal seed layer is not to be located (e.g., where only the first metal seed layer is located and not the second metal seed layer). In some examples, the resist layer is patterned to at least cover the portions of the first metal seed layer within the opening. The operation(s) associated with block 2614 are represented by FIGS. 9 and/or 22 as described above.

At block 2616, the example process involves depositing a second metal seed layer (e.g., the second metal seed layer 204 of FIGS. 2-5, the first metal seed layer 2302 of FIGS. 23-25) with a relatively low sheet resistance onto the substrate at locations exposed through the patterned resist layer. In some examples, the sheet resistance is relatively low based on using a material with a relatively low resistivity. In some examples, the sheet resistance is low based on the seed layer having a relatively large thickness. In some examples, both the material used for the second metal seed layer as well as the thickness of the layer contribute to the relatively low sheet resistance. Depending on whether a stress buffer layer was added (determined at block 2604) and whether the first metal seed layer was removed (determined at block 2610), the second metal seed layer may be deposited directly onto the substrate or with the stress buffer layer and/or the first metal seed layer disposed therebetween. The operation(s) associated with block 2616 are represented by FIGS. 10 and/or 23 as described above.

At block 2618, the example process involves removing the resist layer to expose the previously covered portions of the first metal seed layer. The operation(s) associated with block 2616 are represented by FIGS. 10 and/or 24 as described above. With the second metal seed layer deposited and the first metal seed layer uncovered, the underlying substrate now has two different seed layers with different sheet resistances at different locations. This arrangement can then serve as the basis to implement any further processing such as the formation of an inductor as detailed in FIGS. 11-19 and/or the direct electroplating of a metal (e.g., the metal plating layer 2502 of FIG. 25) onto both seed layers. Thus, in the example process of FIG. 26, the process ends after block 2618, but additional processing may follow in any suitable manner.

As discussed above, some of the operations in the flowchart shown in FIG. 26 can be reordered to achieve different structures and/or similar structures in different ways. For instance, in some examples, blocks 2614-2618 can be moved to occur before block 2610 such that the second metal seed layer is deposited before the first metal seed layer. Further, other arrangements and/or additional processing operations may also be implemented.

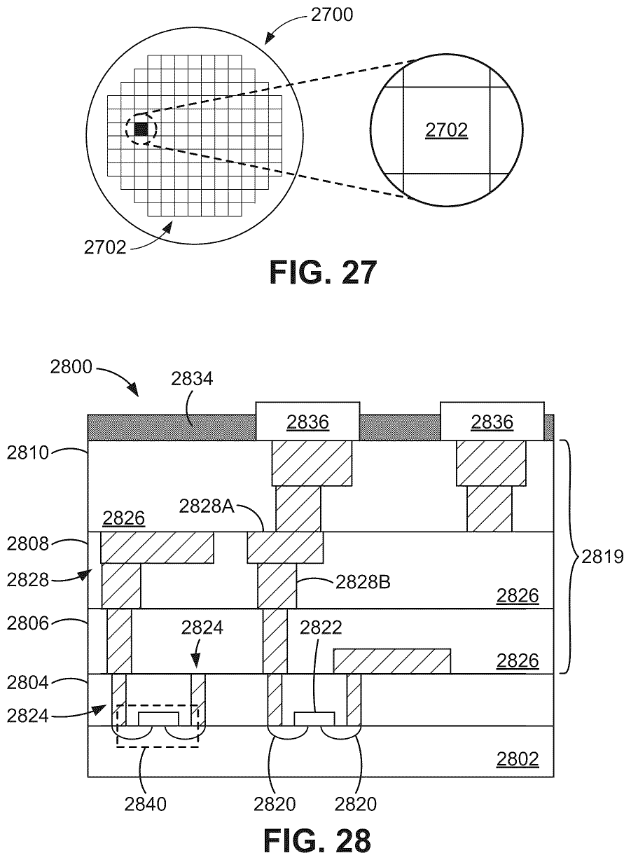

The example hybrid seed layer architectures including both high and low sheet resistance seed layers (e.g., the seed layers 202, 204, 2102, 2302) disclosed herein may be included in any suitable electronic component. FIGS. 27-30 illustrate various examples of apparatus that may include and/or be included in the example IC package 100 of FIG. 1 that contains example hybrid seed layer architectures disclosed herein.

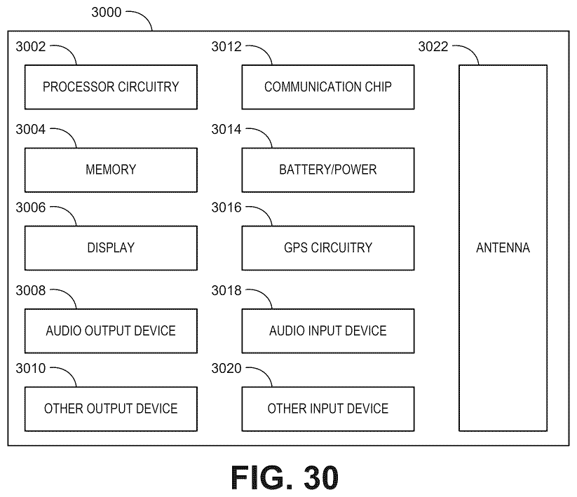

FIG. 27 is a top view of a wafer 2700 and dies 2702 that may be included in the IC package 10 of FIG. 1 (e.g., as any suitable ones of the dies 106, 108) with a substrate that includes one or more of the example hybrid seed layer architectures disclosed herein. The wafer 2700 includes semiconductor material and one or more dies 2702 having circuitry. Each of the dies 2702 may be a repeating unit of a semiconductor product. After the fabrication of the semiconductor product is complete, the wafer 2700 may undergo a singulation process in which the dies 2702 are separated from one another to provide discrete “chips.” The die 2702 includes one or more transistors (e.g., some of the transistors 2840 of FIG. 28, discussed below), supporting circuitry to route electrical signals to the transistors, passive components (e.g., traces, resistors, capacitors, inductors, and/or other circuitry), and/or any other components. In some examples, the die 2702 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 2702. For example, a memory array of multiple memory circuits may be formed on a same die 2702 as programmable circuitry (e.g., the processor circuitry 3002 of FIG. 30) and/or other logic circuitry. Such memory may store information for use by the programmable circuitry. The example IC package 100 disclosed herein may be manufactured using a die-to-wafer assembly technique in which some dies are attached to a wafer 2700 that includes others of the dies, and the wafer 2700 is subsequently singulated.

FIG. 28 is a cross-sectional side view of an IC device 2800 that may be included in the example IC package 100 (e.g., in any one of the dies 106, 108) with a substrate that includes one or more of the example hybrid seed layer architectures disclosed herein. One or more of the IC devices 2800 may be included in one or more dies 2702 (FIG. 27). The IC device 2800 may be formed on a die substrate 2802 (e.g., the wafer 2700 of FIG. 27) and may be included in a die (e.g., the die 2702 of FIG. 27). The die substrate 2802 may be a semiconductor substrate including semiconductor materials including, for example, n-type or p-type materials systems (or a combination of both). The die substrate 2802 may include, for example, a crystalline substrate formed using a bulk silicon or a silicon-on-insulator (SOI) substructure. In some examples, the die substrate 2802 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 2802. Although a few examples of materials from which the die substrate 2802 may be formed are described here, any material that may serve as a foundation for an IC device 2800 may be used. The die substrate 2802 may be part of a singulated die (e.g., the dies 2702 of FIG. 27) or a wafer (e.g., the wafer 2700 of FIG. 27).

The IC device 2800 may include one or more device layers 2804 disposed on and/or above the die substrate 2802. The device layer 2804 may include features of one or more transistors 2840 (e.g., metal oxide semiconductor field-effect transistors (MOSFETs)) formed on the die substrate 2802. The device layer 2804 may include, for example, one or more source and/or drain (S/D) regions 2820, a gate 2822 to control current flow between the S/D regions 2820, and one or more S/D contacts 2824 to route electrical signals to/from the S/D regions 2820. The transistors 2840 may include additional features not depicted for the sake of clarity, such as device isolation regions, gate contacts, and the like. The transistors 2840 are not limited to the type and configuration depicted in FIG. 28 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 2840 may include a gate 2822 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 2840 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 2840 along the source-channel-drain direction, the gate electrode may include a U-shaped structure that includes a bottom portion substantially parallel to the surface of the die substrate 2802 and two sidewall portions that are substantially perpendicular to the top surface of the die substrate 2802. In other examples, at least one of the metal layers that form the gate electrode may be a planar layer that is substantially parallel to the top surface of the die substrate 2802 and does not include sidewall portions substantially perpendicular to the top surface of the die substrate 2802. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 2820 may be formed within the die substrate 2802 adjacent to the gate 2822 of corresponding transistor(s) 2840. The S/D regions 2820 may be formed using an implantation/diffusion process or an etching/deposition process, for example. In the former process, dopants such as boron, aluminum, antimony, phosphorous, or arsenic may be ion-implanted into the die substrate 2802 to form the SD regions 2820. An annealing process that activates the dopants and causes them to diffuse farther into the die substrate 2802 may follow the ion-implantation process. In the latter process, the die substrate 2802 may first be etched to form recesses at the locations of the S/D regions 2820. An epitaxial deposition process may then be carried out to fill the recesses with material that is used to fabricate the S/D regions 2820. In some implementations, the S/D regions 2820 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 2820 may be formed using one or more alternate semiconductor materials such as germanium or a group III-V material or alloy. In further examples, one or more layers of metal and/or metal alloys may be used to form the S/D regions 2820.

Electrical signals, such as power and/or input/output (I/O) signals, may be routed to and/or from the devices (e.g., transistors 2840) of the device layer 2804 through one or more interconnect layers disposed on the device layer 2804 (illustrated in FIG. 28 as interconnect layers 2806-2810). For example, electrically conductive features of the device layer 2804 (e.g., the gate 2822 and the S/D contacts 2824) may be electrically coupled with the interconnect structures 2828 of the interconnect layers 2806-2810. The one or more interconnect layers 2806-2810 may form a metallization stack (also referred to as an “ILD stack”) 2819 of the IC device 2800.

The interconnect structures 2828 may be arranged within the interconnect layers 2806-2810 to route electrical signals according to a wide variety of designs (in particular, the arrangement is not limited to the particular configuration of interconnect structures 2828 depicted in FIG. 28). Although a particular number of interconnect layers 2806-2810 is depicted in FIG. 28, examples of the present disclosure include IC devices having more or fewer interconnect layers than depicted.

In some examples, the interconnect structures 2828 may include lines 2828a and/or vias 2828b filled with an electrically conductive material such as a metal. The lines 2828a may be arranged to route electrical signals in a direction of a plane that is substantially parallel with a surface of the die substrate 2802 upon which the device layer 2804 is formed. For example, the lines 2828a may route electrical signals in a direction in and/or out of the page from the perspective of FIG. 28. The vias 2828b may be arranged to route electrical signals in a direction of a plane that is substantially perpendicular to the surface of the die substrate 2802 upon which the device layer 2804 is formed. In some examples, the vias 2828b may electrically couple lines 2828a of different interconnect layers 2806-2810 together.

The interconnect layers 2806-2810 may include a dielectric material 2826 disposed between the interconnect structures 2828, as shown in FIG. 28. In some examples, the dielectric material 2826 disposed between the interconnect structures 2828 in different ones of the interconnect layers 2806-2810 may have different compositions; in other examples, the composition of the dielectric material 2826 between different interconnect layers 2806-2810 may be the same.

A first interconnect layer 2806 (referred to as Metal 1 or “M1”) may be formed directly on the device layer 2804. In some examples, the first interconnect layer 2806 may include lines 2828a and/or vias 2828b, as shown. The lines 2828a of the first interconnect layer 2806 may be coupled with contacts (e.g., the S/D contacts 2824) of the device layer 2804.

A second interconnect layer 2808 (referred to as Metal 2 or “M2”) may be formed directly on the first interconnect layer 2806. In some examples, the second interconnect layer 2808 may include vias 2828b to couple the lines 2828a of the second interconnect layer 2808 with the lines 2828a of the first interconnect layer 2806. Although the lines 2828a and the vias 2828b are structurally delineated with a line within each interconnect layer (e.g., within the second interconnect layer 2808) for the sake of clarity, the lines 2828a and the vias 2828b may be structurally and/or materially contiguous (e.g., simultaneously filled during a dual-damascene process) in some examples.

A third interconnect layer 2810 (referred to as Metal 3 or “M3”) (and additional interconnect layers, as desired) may be formed in succession on the second interconnect layer 2808 according to similar techniques and/or configurations described in connection with the second interconnect layer 2808 or the first interconnect layer 2806. In some examples, the interconnect layers that are “higher up” in the metallization stack 2819 in the IC device 2800 (i.e., further away from the device layer 2804) may be thicker.

The IC device 2800 may include a solder resist material 2834 (e.g., polyimide or similar material) and one or more conductive contacts 2836 formed on the interconnect layers 2806-2810. In FIG. 28, the conductive contacts 2836 are illustrated as taking the form of bond pads. The conductive contacts 2836 may be electrically coupled with the interconnect structures 2828 and configured to route the electrical signals of the transistor(s) 2840 to other external devices. For example, solder bonds may be formed on the one or more conductive contacts 2836 to mechanically and/or electrically couple a chip including the IC device 2800 with another component (e.g., a circuit board). The IC device 2800 may include additional or alternate structures to route the electrical signals from the interconnect layers 2806-2810; for example, the conductive contacts 2836 may include other analogous features (e.g., posts) that route the electrical signals to external components.

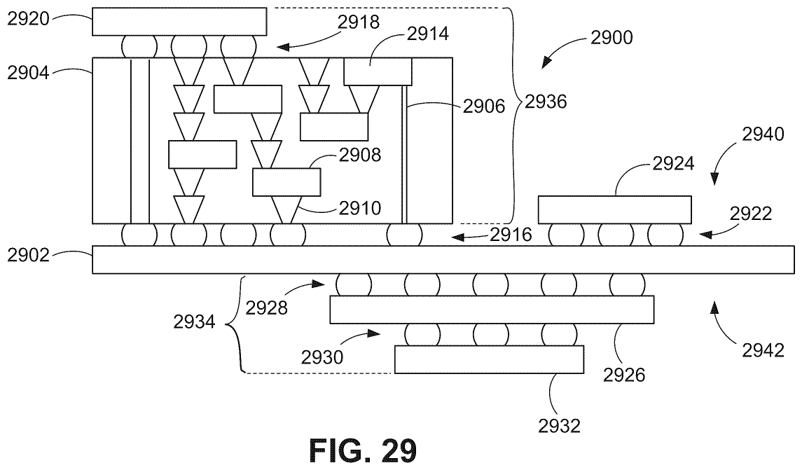

FIG. 29 is a cross-sectional side view of an IC device assembly 2900 that may include the example IC package 100 of FIG. 1 with a substrate that includes one or more of the example hybrid seed layer architectures disclosed herein. In some examples, the IC device assembly corresponds to the example IC package 100 of FIG. 1. The IC device assembly 2900 includes a number of components disposed on a circuit board 2902 (which may be, for example, a motherboard). The IC device assembly 2900 includes components disposed on a first face 2940 of the circuit board 2902 and an opposing second face 2942 of the circuit board 2902; generally, components may be disposed on one or both faces 2940 and 2942. Any of the IC packages discussed below with reference to the IC device assembly 2200 may take the form of the example IC package 100 of FIG. 1.

In some examples, the circuit board 2902 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2902. In other examples, the circuit board 2902 may be a non-PCB substrate.

The IC device assembly 2900 illustrated in FIG. 29 includes a package-on-interposer structure 2936 coupled to the first face 2940 of the circuit board 2902 by coupling components 2916. The coupling components 2916 may electrically and mechanically couple the package-on-interposer structure 2936 to the circuit board 2902, and may include solder balls (as shown in FIG. 29), male and female portions of a socket, an adhesive, an underfill material, and/or any other suitable electrical and/or mechanical coupling structure.

The package-on-interposer structure 2936 may include an IC package 2920 coupled to an interposer 2904 by coupling components 2918. The coupling components 2918 may take any suitable form for the application, such as the forms discussed above with reference to the coupling components 2916. Although a single IC package 2920 is shown in FIG. 29, multiple IC packages may be coupled to the interposer 2904; indeed, additional interposers may be coupled to the interposer 2904. The interposer 2904 may provide an intervening substrate used to bridge the circuit board 2902 and the IC package 2920. The IC package 2920 may be or include, for example, a die (the die 2702 of FIG. 27), an IC device (e.g., the IC device 2800 of FIG. 28), or any other suitable component. Generally, the interposer 2904 may spread a connection to a wider pitch or reroute a connection to a different connection. For example, the interposer 2904 may couple the IC package 2920 (e.g., a die) to a set of BGA conductive contacts of the coupling components 2916 for coupling to the circuit board 2902. In the example illustrated in FIG. 29, the IC package 2920 and the circuit board 2902 are attached to opposing sides of the interposer 2904; in other examples, the IC package 2920 and the circuit board 2902 may be attached to a same side of the interposer 2904. In some examples, three or more components may be interconnected by way of the interposer 2904.

In some examples, the interposer 2904 may be formed as a PCB, including multiple metal layers separated from one another by layers of dielectric material and interconnected by electrically conductive vias. In some examples, the interposer 2904 may be formed of an epoxy resin, a fiberglass-reinforced epoxy resin, an epoxy resin with inorganic fillers, a ceramic material, or a polymer material such as polyimide. In some examples, the interposer 2904 may be formed of alternate rigid or flexible materials that may include the same materials described above for use in a semiconductor substrate, such as silicon, germanium, and other group III-V and group IV materials. The interposer 2904 may include metal interconnects 2908 and vias 2910, including but not limited to through-silicon vias (TSVs) 2906. The interposer 2904 may further include embedded devices 2914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2904. The package-on-interposer structure 2936 may take the form of any of the package-on-interposer structures known in the art.

The IC device assembly 2900 may include an IC package 2924 coupled to the first face 2940 of the circuit board 2902 by coupling components 2922. The coupling components 2922 may take the form of any of the examples discussed above with reference to the coupling components 2916, and the IC package 2924 may take the form of any of the examples discussed above with reference to the IC package 2920.

The IC device assembly 2900 illustrated in FIG. 29 includes a package-on-package structure 2934 coupled to the second face 2942 of the circuit board 2902 by coupling components 2928. The package-on-package structure 2934 may include a first IC package 2926 and a second IC package 2932 coupled together by coupling components 2930 such that the first IC package 2926 is disposed between the circuit board 2902 and the second IC package 2932. The coupling components 2928, 2930 may take the form of any of the examples of the coupling components 2916 discussed above, and the IC packages 2926, 2932 may take the form of any of the examples of the IC package 2920 discussed above. The package-on-package structure 2934 may be configured in accordance with any of the package-on-package structures known in the art.

FIG. 30 is a block diagram of an example electrical device 3000 that may include one or more of the example IC package 100 of FIG. 1 with a substrate that includes one or more of the example hybrid seed layer architectures disclosed herein. For example, any suitable ones of the components of the electrical device 3000 may include one or more of the device assemblies 2900. IC devices 2800, or dies 2702 disclosed herein, and may be arranged in the example IC package 100. A number of components are illustrated in FIG. 30 as included in the electrical device 3000, but any one or more of these components may be omitted or duplicated, as suitable for the application. In some examples, some or all of the components included in the electrical device 3000 may be attached to one or more motherboards. In some examples, some or all of these components are fabricated onto a single system-on-a-chip (SoC) die.

Additionally, in various examples, the electrical device 3000 may not include one or more of the components illustrated in FIG. 30, but the electrical device 3000 may include interface circuitry for coupling to the one or more components. For example, the electrical device 3000 may not include a display 3006, but may include display interface circuitry (e.g., a connector and driver circuitry) to which a display 3006 may be coupled. In another set of examples, the electrical device 3000 may not include an audio input device 3018 (e.g., microphone) or an audio output device 3008 (e.g., a speaker, a headset, earbuds, etc.), but may include audio input or output device interface circuitry (e.g., connectors and supporting circuitry) to which an audio input device 3018 or audio output device 3008 may be coupled.

The electrical device 3000 may include programmable circuitry 3002 (e.g., one or more processing devices). The programmable circuitry 3002 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 3000 may include a memory 3004, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 3004 may include memory that shares a die with the programmable circuitry 3002. This memory may be used as cache memory and may include embedded dynamic random access memory (eDRAM) or spin transfer torque magnetic random access memory (STT-MRAM).

In some examples, the electrical device 3000 may include a communication chip 3012 (e.g., one or more communication chips). For example, the communication chip 3012 may be configured for managing wireless communications for the transfer of data to and from the electrical device 3000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 3012 may implement any of a number of wireless standards or protocols, including but not limited to Institute for Electrical and Electronic Engineers (IEEE) standards including Wi-Fi (IEEE 802.11 family). IEEE 802.16 standards (e.g., IEEE 802.16-2805 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 3012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 3012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 3012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 3012 may operate in accordance with other wireless protocols in other examples. The electrical device 3000 may include an antenna 3022 to facilitate wireless communications and/or to receive other wireless communications (such as AM or FM radio transmissions).

In some examples, the communication chip 3012 may manage wired communications, such as electrical, optical, or any other suitable communication protocols (e.g., the Ethernet). As noted above, the communication chip 3012 may include multiple communication chips. For instance, a first communication chip 3012 may be dedicated to shorter-range wireless communications such as Wi-Fi or Bluetooth, and a second communication chip 3012 may be dedicated to longer-range wireless communications such as global positioning system (GPS), EDGE, GPRS, CDMA, WiMAX, LTE, EV-DO, or others. In some examples, a first communication chip 3012 may be dedicated to wireless communications, and a second communication chip 3012 may be dedicated to wired communications.

The electrical device 3000 may include battery/power circuitry 3014. The battery/power circuitry 3014 may include one or more energy storage devices (e.g., batteries or capacitors) and/or circuitry for coupling components of the electrical device 3000 to an energy source separate from the electrical device 3000 (e.g., AC line power).

The electrical device 3000 may include a display 3006 (or corresponding interface circuitry, as discussed above). The display 3006 may include any visual indicators, such as a heads-up display, a computer monitor, a projector, a touchscreen display, a liquid crystal display (LCD), a light-emitting diode display, or a flat panel display.

The electrical device 3000 may include an audio output device 3008 (or corresponding interface circuitry, as discussed above). The audio output device 3008 may include any device that generates an audible indicator, such as speakers, headsets, or earbuds.

The electrical device 3000 may include an audio input device 3018 (or corresponding interface circuitry, as discussed above). The audio input device 3018 may include any device that generates a signal representative of a sound, such as microphones, microphone arrays, or digital instruments (e.g., instruments having a musical instrument digital interface (MIDI) output).

The electrical device 3000 may include GPS circuitry 3016. The GPS circuitry 3016 may be in communication with a satellite-based system and may receive a location of the electrical device 3000, as known in the art.

The electrical device 3000 may include any other output device 3010 (or corresponding interface circuitry, as discussed above). Examples of the other output device 3010 may include an audio codec, a video codec, a printer, a wired or wireless transmitter for providing information to other devices, or an additional storage device.

The electrical device 3000 may include any other input device 3020 (or corresponding interface circuitry, as discussed above). Examples of the other input device 3020 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 3000 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 3000 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A. (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”. “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that implement hybrid seed layer architectures that include both high and low sheet resistance metal seed layers at different locations. Specifically, in some examples, the low sheet resistance metal seed layer is applied across the bulk of an underlying substrate to carry current across relatively large areas to be electroplated (e.g., entire cores, wafers, and/or panels) so as to provide an equipotential plane that facilitates the uniform and reliable electroplating of metal onto the underlying substrate. The high sheet resistance metal seed layer is positioned (e.g., exposed) at localized areas (e.g., within vias or other openings) where a low sheet resistance metal seed layer is either too thick to enable reliable electroplating (e.g., within a narrow/high aspect ratio via) and/or where the low sheet resistance undermines the functionality of components (e.g., inductors) intended at the corresponding locations.

Further examples and combinations thereof include the following:

Example 1 includes an integrated circuit package comprising a substrate having a first surface and a second surface opposite the first surface, a first seed layer on a sidewall of an opening in the substrate, the opening to extend from the first surface toward the second surface, and a second seed layer on the first surface of the substrate, the second seed layer spaced apart from the opening.

Example 2 includes the integrated circuit package of example 1, wherein at least a portion of the first seed layer is on the first surface between the substrate and the second seed layer.

Example 3 includes the integrated circuit package of example 2, wherein the at least the portion of the first seed layer is a first portion of the first seed layer, a second portion of the first seed layer on the first surface adjacent an end of the opening, the second portion of the first seed layer is a continuous extension of the first portion of the first seed layer on the sidewall of the opening, and the second seed layer is spaced apart from the second portion of the first seed layer.

Example 4 includes the integrated circuit package of any one of examples 1-3, wherein the first seed layer has a first sheet resistance, and the second seed layer has a second sheet resistance, the first sheet resistance higher than the second sheet resistance.

Example 5 includes the integrated circuit package of example 4, wherein the first sheet resistance is greater than 1 ohms per square and the second sheet resistance is less than example 0 includes 5 ohms per square.

Example 6 includes the integrated circuit package of any one of examples 1-5, further including a magnetic material in contact with the first seed layer along the sidewall of the opening, the first seed layer between the magnetic material and the sidewall of the opening.

Example 7 includes the integrated circuit package of any one of examples 1-6, wherein the first seed layer has a first thickness, and the second seed layer has a second thickness, the second thickness at least twice the first thickness.

Example 8 includes the integrated circuit package of example 7, wherein the first thickness is less than 20 nanometers.

Example 9 includes the integrated circuit package of any one of examples 1-8, wherein the first seed layer includes multiple layers of material, the multiple layers of material including an adhesion layer and a protective cap layer, the adhesion layer between the protective cap layer and the substrate.

Example 10 includes the integrated circuit package of example 9, wherein the adhesion layer includes at least one of titanium or tantalum, and the protective cap layer includes ruthenium.

Example 11 includes the integrated circuit package of any one of examples 1-10, wherein the substrate includes silicon, and the opening is a through-silicon via.

Example 12 includes the integrated circuit package of any one of examples 1-10, wherein the substrate is a glass core of a package substrate, and the opening is a through glass via.

Example 13 includes the integrated circuit package of example 12, further including a polymeric layer between the first seed layer and the substrate.

Example 14 includes an integrated circuit package comprising a substrate including a via extending from a first surface of the substrate toward a second surface of the substrate, a first conductive layer on an inner surface of the via, the first conductive layer having a first thickness, and a second conductive layer on the first surface of the substrate, the second conductive layer having a second thickness, the second thickness greater than the first thickness.

Example 15 includes the integrated circuit package of example 14, wherein the first conductive layer includes a first material, and the second conductive layer includes a second material different than the first materials.

Example 16 includes the integrated circuit package of example 15, wherein the first material includes at least one of ruthenium, titanium, tantalum, manganese, or cobalt.

Example 17 includes the integrated circuit package of any one of examples 15 or 16, wherein the second material includes copper.

Example 18 includes the integrated circuit package of any one of examples 14-17, wherein a portion of the first conductive layer is on the first surface, the second conductive layer in contact with the portion of the first conductive layer.

Example 19 includes a method comprising depositing a first seed layer onto a substrate, the first seed layer deposited onto a wall of an opening extending through the substrate, and depositing a second seed layer onto the substrate, the second seed layer not deposited inside the opening of the substrate, the second seed layer thicker than the first seed layer.

Example 20 includes the method of example 19, wherein the second seed layer is to cover a portion of the first seed layer.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit package comprising:
a substrate having a first surface and a second surface opposite the first surface;
a first seed layer on a sidewall of an opening in the substrate, the opening to extend from the first surface toward the second surface; and
a second seed layer on the first surface of the substrate, the second seed layer spaced apart from the opening.

2. The integrated circuit package of claim 1, wherein at least a portion of the first seed layer is on the first surface between the substrate and the second seed layer.

3. The integrated circuit package of claim 2, wherein the at least the portion of the first seed layer is a first portion of the first seed layer, a second portion of the first seed layer on the first surface adjacent an end of the opening, the second portion of the first seed layer is a continuous extension of the first portion of the first seed layer on the sidewall of the opening, and the second seed layer is spaced apart from the second portion of the first seed layer.

4. The integrated circuit package of claim 1, wherein the first seed layer has a first sheet resistance, and the second seed layer has a second sheet resistance, the first sheet resistance higher than the second sheet resistance.

5. The integrated circuit package of claim 4, wherein the first sheet resistance is greater than 1 ohms per square and the second sheet resistance is less than 0.5 ohms per square.

6. The integrated circuit package of claim 1, further including a magnetic material in contact with the first seed layer along the sidewall of the opening, the first seed layer between the magnetic material and the sidewall of the opening.

7. The integrated circuit package of claim 1, wherein the first seed layer has a first thickness, and the second seed layer has a second thickness, the second thickness at least twice the first thickness.

8. The integrated circuit package of claim 7, wherein the first thickness is less than 20 nanometers.

9. The integrated circuit package of claim 1, wherein the first seed layer includes multiple layers of material, the multiple layers of material including an adhesion layer and a protective cap layer, the adhesion layer between the protective cap layer and the substrate.

10. The integrated circuit package of claim 9, wherein the adhesion layer includes at least one of titanium or tantalum, and the protective cap layer includes ruthenium.

11. The integrated circuit package of claim 1, wherein the substrate includes silicon, and the opening is a through-silicon via.

12. The integrated circuit package of claim 1, wherein the substrate is a glass core of a package substrate, and the opening is a through glass via.

13. The integrated circuit package of claim 12, further including a polymeric layer between the first seed layer and the substrate.

14. An integrated circuit package comprising:
a substrate including a via extending from a first surface of the substrate toward a second surface of the substrate;
a first conductive layer on an inner surface of the via, the first conductive layer having a first thickness; and
a second conductive layer on the first surface of the substrate, the second conductive layer having a second thickness, the second thickness greater than the first thickness.

15. The integrated circuit package of claim 14, wherein the first conductive layer includes a first material, and the second conductive layer includes a second material different than the first materials.

16. The integrated circuit package of claim 15, wherein the first material includes at least one of ruthenium, titanium, tantalum, manganese, or cobalt.

17. The integrated circuit package of claim 15, wherein the second material includes copper.

18. The integrated circuit package of claim 14, wherein a portion of the first conductive layer is on the first surface, the second conductive layer in contact with the portion of the first conductive layer.

19. A method comprising:
depositing a first seed layer onto a substrate, the first seed layer deposited onto a wall of an opening extending through the substrate; and
depositing a second seed layer onto the substrate, the second seed layer not deposited inside the opening of the substrate, the second seed layer thicker than the first seed layer.

20. The method of claim 19, wherein the second seed layer is to cover a portion of the first seed layer.
